(19) United States
(12) Patent Application Publication
(10) Pub. No.: US 2016/0246712 A1
(43) Pub. Date: Aug. 25, 2016

(54) INDIRECTION DATA STRUCTURES IMPLEMENTED AS RECONFIGURABLE HARDWARE

(71) Applicant: HGST Netherlands B.V., Amsterdam (NL)

(72) Inventors: Dejan VUCINIC, San Jose, CA (US); Zvonimir Z. BANDIC, San Jose, CA (US); Filip BLAGOJEVIC, San Jose, CA (US); Cyril GUYOT, San Jose, CA (US); Robert MATEESCU, San Jose, CA (US); Qingbo WANG, Irvine, CA (US)

(21) Appl. No.: 14/631,117

(22) Filed: Feb. 25, 2015

(51) Int. Cl. G06F 12/02; G11C 14/00; G06F 12/06

(52) U.S. Cl. CPC G06F 12/0246; G06F 12/0638; G06F 12/0692; G11C 14/0045; G11C 14/0036; G11C 14/0081; G11C 14/009; G06F 2212/7201; G06F 2212/205; G11C 13/0069

(57) ABSTRACT

Methods and systems for implementing indirection data structures as reconfigurable hardware are provided. The controller can configure a logic circuit to execute a first function, receive a first command from a host comprising a request for data from a logical address, and execute the first command by accessing the memory at a first physical address. The controller can also re-configure the logic circuit to execute a second function, receive a second command comprising a request for data from the logical address, and execute the second command by accessing the memory at the second physical address. The logic circuit can also generate the first physical address corresponding to the logical address, in response to the first command, by executing the first function and generate the second physical address corresponding to the logical address, in response to the second command, by executing the second function.

### FIELD OF THE DISCLOSURE

The present disclosure relates to systems and methods for implementing indirection data structures implemented as reconfigurable hardware.

### RELATED DISCLOSURE

Non-volatile solid state devices (SSDs) are widely used for primary and secondary storage in computer systems. The density and size of non-volatile SSDs, for example, flash memories, has increased with semiconductor scaling. Consequently, the cell size has decreased, which results in low native endurance (operational lifetime). Low endurance of non-volatile SSDs can severely limit the applications that the SSDs could be used for and can have severe impacts for solid state device applications.

In addition, different areas of a non-volatile memory, for example, a flash storage memory, deteriorate unevenly with time. Therefore, flash storage cells of the same flash storage memory can exhibit different error counts when writing to or reading from the flash storage memory. The difference in the error counts of the flash memory cells is a function of many parameters, for example, fabrication technology, cell impurities, and cell usage. For example, if one cell has more impurities compared to another cell in the same flash storage memory, then it will exhibit a higher number of error counts compared to a cell with less impurities. Moreover, cells who are accessed more frequently, because, for example, of read-write traffic patterns, can also exhibit a higher number of error counts compared to other cells that are less frequently accessed.

Modern non-volatile SSDs use indirection to improve their reliability and increase their endurance. Indirection or indirect addressing is a technique where the physical address associated with a particular memory access is held in an intermediate location, e.g., a lookup table, so that the physical address is first “looked up” and then used, for example, to locate the data itself if, for example, the memory access is a read request. A logical address is provided into the table and the physical access in the storage device is returned. Therefore, an indirection table can keep track of the logical-to-physical mapping of a particular memory block. The indirection table should be consulted on each requested memory access to obtain the physical location of the particular block associated with the memory access.

Using an indirection table to perform address mapping can increase the endurance of an SSD, for example, by mapping particular logical addresses to different physical addresses over time. If for example, a particular traffic pattern results in writing to and/or reading from a specific logical address, the indirection table can change the logical to physical mapping periodically, such that different physical memory blocks are accessed over time, when the traffic pattern involves accessing the same logical address. This can result in a uniform wear-out of the storage device.

Indirection can also be used to hide underlying write failures of particular memory blocks. For example, when a write to a particular physical block fails, the memory controller can remap the logical address to another physical location on the memory device, and can record the mapping such that future reads can receive the requested data from the correct physical address. In this manner, the memory controller can transparently improve reliability of the SSD without requiring any physical changes or replacements.

Indirection tables in existing memory controllers are typically stored in static RAMs (SRAMs) or dynamic RAMs (DRAMs). However, SRAMs exhibit leakage power, which can increase the total power consumption of implementing the indirection table, and DRAMs, while less power-hungry, are slower than SRAMs. In addition, every lookup into the SRAM or DRAM can take several clock cycles. Emerging non-volatile memories, such as Phase Change Memory (PCM), have very short latencies, and therefore, the several clock cycles required for the lookup in SRAMs or DRAMs become a non-negligible contribution to the total SSD access latency.

### SUMMARY

The present disclosure relates to methods, systems, and computer program products for implementing indirection data structures implemented as reconfigurable hardware. According to aspects of the disclosure, a method of performing operations in a communications protocol can include providing a target in communication with a host and a memory, wherein the target comprises a logic circuit and configuring the logic circuit to execute a first function. The method can also include receiving a first command from the host comprising a request for data from a logical address, generating, by the logic circuit, a first physical address corresponding to the logical address, in response to the first command, and executing, by the target, the first command to provide the requested data by accessing the memory at the first physical address. The method can also include re-configuring the logic circuit to execute a second function. The method can further include receiving a second command from the host comprising a request for data from the logical address, generating a second physical address corresponding to the logical address, in response to the second command, and executing, by the target, the second command to provide the requested data by accessing the memory at the second physical address.

According to aspects of the disclosure, a method of performing operations in a communications protocol can include providing a target in communication with a host and a memory, wherein the memory comprises a logic circuit and configuring the logic circuit to execute a first function. The method can also include receiving a first command from the host comprising a request for data from a logical address, generating, by the logic circuit, a first physical address corresponding to the logical address, in response to the first command, and executing, by the target, the first command to provide the requested data by accessing the memory at the first physical address. The method can also include re-configuring the logic circuit to execute a second function. The method can further include receiving a second command from the host comprising a request for data from the logical address, generating a second physical address corresponding to the logical address, in response to the second command, and executing, by the target, the second command to provide the requested data by accessing the memory at the second physical address.

According to aspects of the disclosure, a memory controller can comprise a controller module in communication with a host and a memory, where the controller module can comprise a logic circuit. The controller module can be configured to configure the logic circuit to execute a first function, receive a first command from the host comprising a request for data from a logical address, and execute the first command to provide the requested data by accessing the memory at a first physical address. The controller module can be further be configured to re-configure the logic circuit to execute a second function, receive a second command comprising a request for data from the logical address, and execute the second command to provide the requested data by accessing the memory at the second physical address. According to aspects of the disclosure, the logic circuit can be configured to generate the first physical address corresponding to the logical address, in response to the first command, by executing the first function, and to generate the second physical address corresponding to the logical address, in response to the second command, by executing the second function.

According to aspects of the disclosure, a memory controller can comprise a controller module in communication with a host and a memory comprising a logic circuit. The controller module can be configured to configure the logic circuit to execute a first function, receive a first command from the host comprising a request for data from a logical address, and execute the first command to provide the requested data by accessing the memory at a first physical address. The controller module can be further be configured to re-configure the logic circuit to execute a second function, receive a second command comprising a request for data from the logical address, and execute the second command to provide the requested data by accessing the memory at the second physical address. According to aspects of the disclosure, the logic circuit can be configured to generate the first physical address corresponding to the logical address, in response to the first command, by executing the first function, and to generate the second physical address corresponding to the logical address, in response to the second command, by executing the second function.

### BRIEF DESCRIPTION OF THE DRAWINGS

Various objects, features, and advantages of the present disclosure can be more fully appreciated with reference to the following detailed description when considered in connection with the following drawings, in which like reference numerals identify like elements. The following drawings are for the purpose of illustration only and are not intended to be limiting of the invention, the scope of which is set forth in the claims that follow.

FIG. 1 illustrates an exemplary system implementing a communication protocol, in accordance with embodiments of the present disclosure.

FIGS. 2A-2B illustrate an exemplary implementation of an indirection table.

FIG. 3A-3B illustrate an exemplary implementation of indirection, in accordance with embodiments of the present disclosure.

FIG. 4 illustrates an exemplary method for implementing indirection, in accordance with embodiments of the present disclosure.

### DETAILED DESCRIPTION

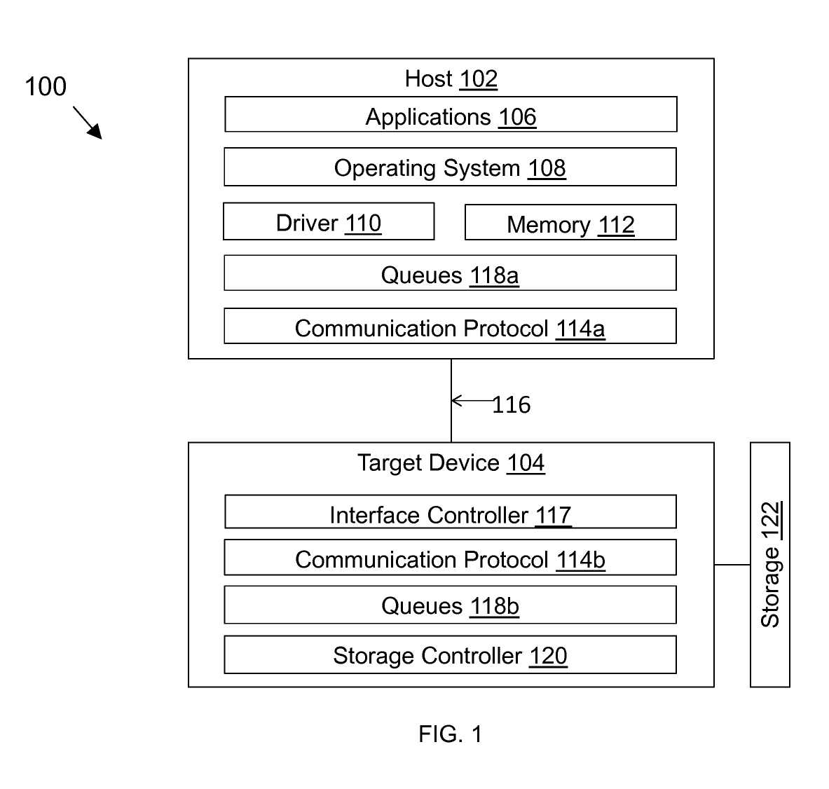

FIG. 1 illustrates an exemplary system 100 implementing a communication protocol, in accordance with embodiments of the present disclosure. System 100 includes host 102 in communication with target device 104 and storage 122. Host 102 includes user applications 106, operating system 108, driver 110, host memory 112, queues 118a, and communication protocol 114a. Target device 104 includes interface controller 117, communication protocol 114b, queues 118b, and storage controller 120 in communication with storage 122.

Host 102 can run user-level applications 106 on operating system 108. Operating system 108 can run driver 110 that interfaces with host memory 112. In some embodiments, memory 112 can be a DRAM. Host memory 112 can use queues 118a to store commands from host 102 for target 104 to process. Examples of stored or enqueued commands can include read or write operations from host 102. Communication protocol 114a can allow host 102 to communicate with target device 104 using interface controller 117.

Target device 104 can communicate with host 102 using interface controller 117 and communication protocol 114b. Communication protocol 114b can provide queues 118 to access storage 122 via storage controller 120. For example, user-level applications 106 can generate storage memory 122 access requests for data. Those requests can include logical addresses that can correspond to physical addresses of data in storage memory 122. Target device 104 can implement the indirection mechanisms for providing the mapping between the logical and physical addresses. For example, the indirection table can be implemented within storage controller 120.

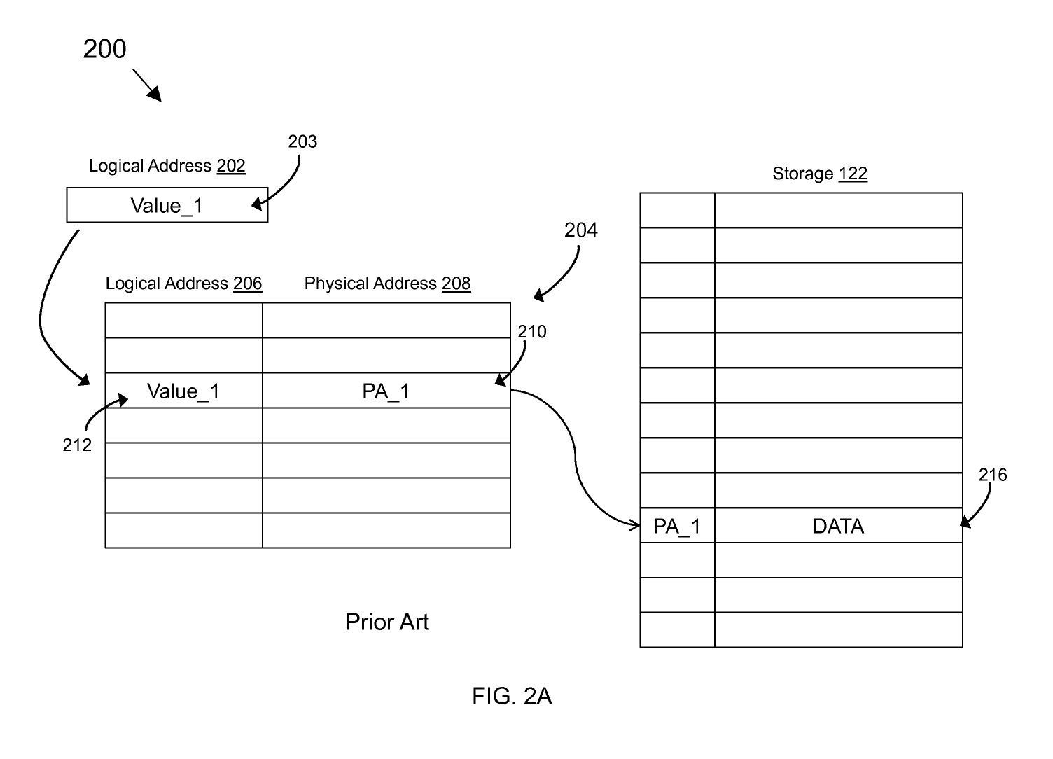

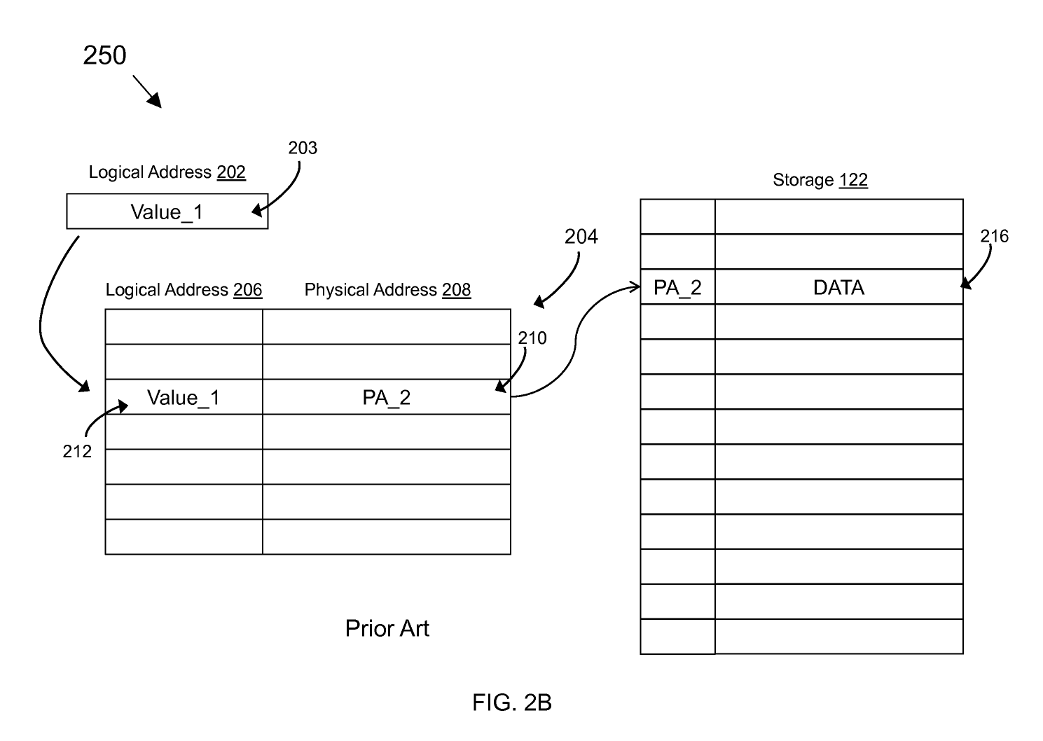

As discussed above, non-volatile solid state devices accumulate failures with use and, therefore, require an indirection mechanism to maximize the operational lifetime of the medium. Because non-volatile memory blocks become unusable after a certain number of accesses (write/read), indirection can spread the write load across memory blocks evenly and thus can ensure that no particularly popular block will cause the device to fail sooner than expected. The physical target location of every read and/or write request to the target device can be resolved using a lookup into an indirection table. This is illustrated in FIGS. 2A and 2B.

FIG. 2A shows an exemplary logical-to-physical address translation 200. Specifically, an application running on host 102 can request data from storage 122. The read request from host can specify a logical address 202, which can have a value, for example, of “Value_1” (203). When target device 104 receives the read request with logical address 202 it can perform a lookup in indirection table 204, which provides the mapping of logical addresses into physical addresses. Specifically, for each logical address listed in logical address column 206, indirection table 204 stores a corresponding physical address in physical address column 208. For example, Value_1 (203) can be stored in location 212 in indirection table 204. When target 104 accesses the particular location 212, it can retrieve the corresponding physical access, shown as PA_1 (210) in FIG. 2A. Once target 104 has the physical address associated with the read request it can access storage 122 to retrieve the requested DATA (216) stored in physical location PA_1.

As discussed above, the logical-to-physical address mappings can change periodically. Specifically, a particular logical address can be remapped to a different physical address. This is illustrated in FIG. 2B generally at 250. A write request to the same logical address (202) can result in data being written to a different physical address. Specifically, host 102 can issue a write request to logical address (202) with value Value_1 (203). When target device 104 receives the write request with logical address 202 it can perform a lookup in indirection table 204. After the remapping, indirection table 204 can store a different corresponding physical address in physical address column 208. For example, Value_1 (203) can be stored in location 212 in indirection table 204, but now the corresponding physical address (210) has a different value, shown as PA_2 in FIG. 2B. When target 104 accesses the indirection table at location (212) corresponding to logical address 202, it can retrieve the new corresponding physical access, PA_2. Once target 104 has the physical address associated with the write request it can access storage 122 to write the DATA 216 in physical location PA_2. Any subsequent read requests to logical address “Value_1” will be translated into a physical address of PA_2, until the indirection table changes again.

In the examples illustrated in FIGS. 2A and 2B, indirection table 204 can be stored in an SRAM or DRAM in the target device and accessed by a state machine or embedded microprocessor handling read/write requests. Therefore every lookup into the SRAM or DRAM can take several clock cycles. However, emerging non-volatile memories, such as Phase Change Memory (PCM), have very short latencies, and therefore, the several clock cycles required for the lookup in SRAMs or DRAMs become a non-negligible contribution to the total SSD access latency. According to aspects of the present disclosure, the entire indirection table can be encoded as combinatorial logic, for example, as field programmable gate array (FPGA) logic. Therefore, the indirection latency for a SSD access can be shortened to the signal propagation delay through the logic circuit that translates the logical address to the corresponding physical address. In modern integrated circuits, the propagation delay mainly depends on the length of wiring between logic elements. Therefore, because the routing for each table can be different, the propagation delay can vary between different implementations of the indirection table. However, especially for smaller tables, the propagation delay can be made faster than the several clock cycles required to perform a DRAM fetch.

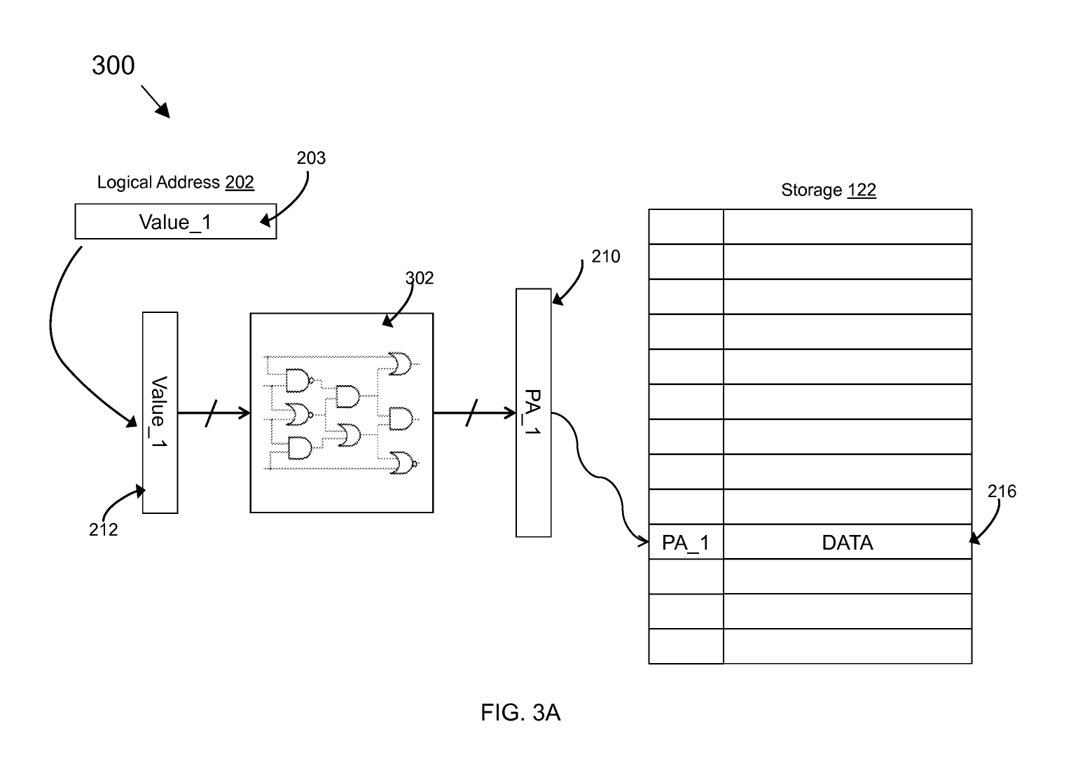

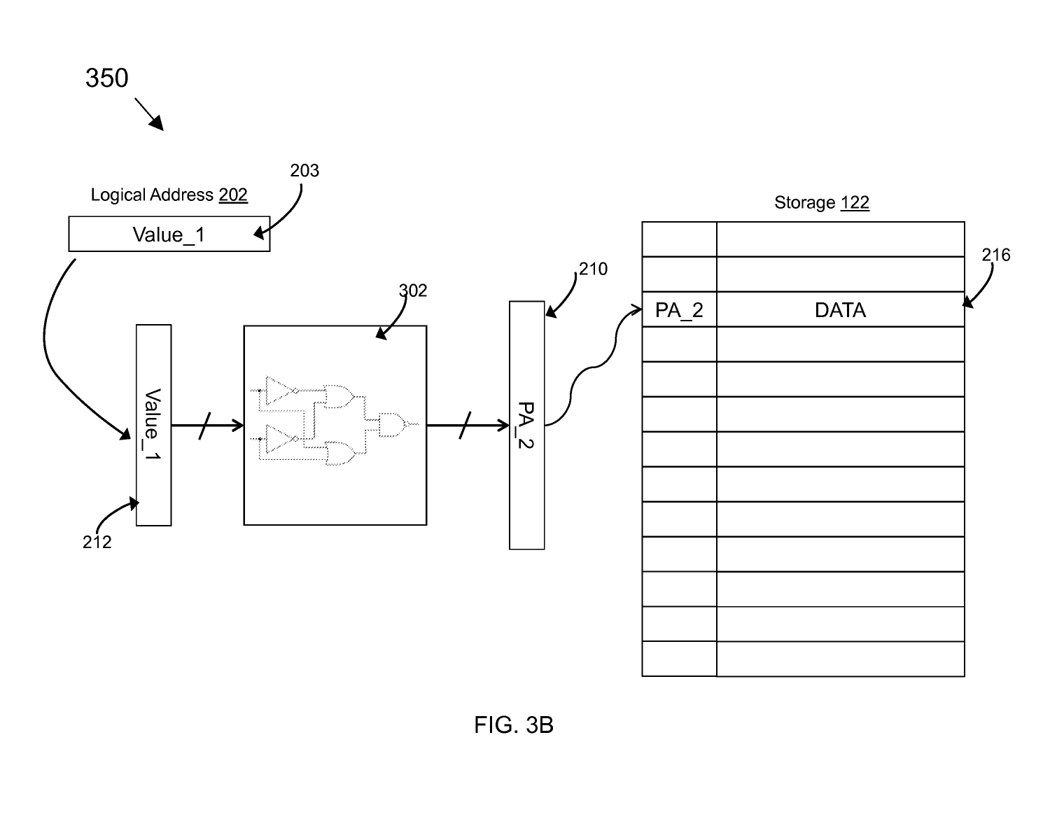

An illustrative implementation of indirection according to aspects of the present disclosure is shown in FIG. 3A generally at 300. Similar to FIGS. 2A and 2B, an application running on host 102 can request data from storage 122. The read request from host can specify a logical address 202, which can have the same value as shown in FIGS. 2A and 2B, for example, “Value_1” (203). When target device 104 receives the read request with logical address 202, it will provide the logical address value, i.e., Value_1, to logic circuit 302 as an input value (304). Logic circuit 302 can calculate the corresponding physical address and provide the physical address value as an output value (306). Logic circuit 302 can be synthesized to provide at its output a value corresponding to PA_1. In addition, logical circuit 302 can be synthesized to calculate a corresponding physical address for every logical address. Every output value of the logic circuit 302 can be stored in a register after the propagation delay of the logic circuit. Once target 104 has the physical address associated with the read request it can access storage 122 to retrieve the requested DATA (216) stored in physical location PA_1.

According to aspects of the present disclosure, when a write request requires alteration of logical-to-physical mapping, a new logic circuit can be compiled and synthesized into target 104. For example, a new logic circuit can be “hot-swapped” through partial reconfiguration into an FPGA that implements target 104. FPGAs can allow part of the logic to be reconfigured on the fly, even while the rest of the chip is operating. The alteration of the logic circuit that performs the mapping can involve the invocation of circuit layout tools on host 102. This step, however, happens infrequently, and can be pre-computed and a collection of subsequent logic circuits can be kept in the device driver 110 for quick reconfiguration when a trigger condition happens, for example, failure to write to a particular memory block. Other trigger conditions can include, for example, reaching a threshold number of writes to a block, reaching a threshold number of writes to the entire device, or reaching a threshold time in operation. According to aspects of the present disclosure, the logic circuit that performs the mapping can be implemented in phase change memory (PCM), magnetoresistive random-access memory (MRAM), or resistive random-access memory (ReRAM). According to aspects of the present disclosure, the logic circuit can be implemented in storage 122.

A reconfigured logic circuit is shown in FIG. 3B. Specifically, circuit 302 has different logic from the circuit depicted in FIG. 3A. Therefore, a write request to the same logical address (202) can result in data being written to a different physical address. As discussed above, host 102 can issue a write request to logical address (202) with value Value_1 (203). When target device 104 receives the write request with logical address 202 it can provide the logical address value, i.e., Value_1, to logic circuit 302 as an input value (304). Logic circuit 302 can calculate the corresponding physical address and provide the physical address value as an output value (306). However, logic circuit 302 has been reconfigured and can provide a different output, for example, logic circuit 302 can provide an output value corresponding to PA_2. Once target 104 has the physical address associated with the write request it can access storage 122 to write the DATA 216 in physical location PA_2.

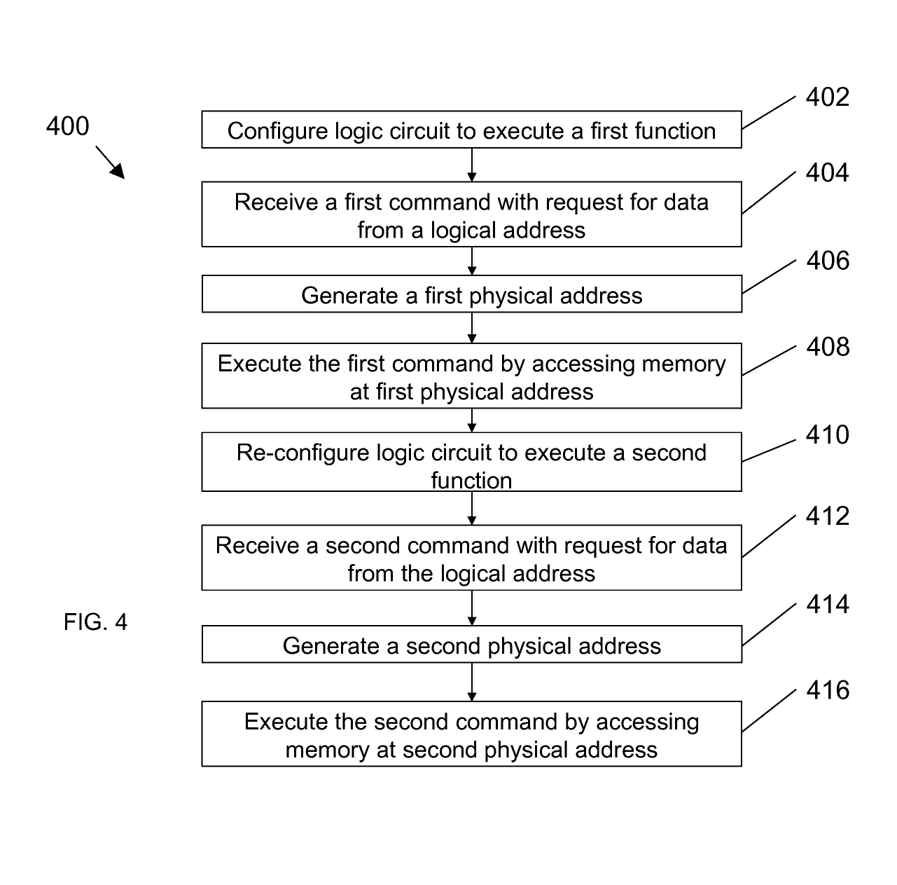

FIG. 4 illustrates an exemplary method 400 for implementing indirection according to aspects of the present disclosure. Specifically, a logic circuit is first configured to execute a first function, or mapping of the logical addresses to physical addresses (step 402). Then the target can receive a first command comprising a request for data from a logical address (step 404) and the logic circuit can generate a first physical address corresponding to the received logical address (step 406). Once the target has the physical address, it can execute the first command to provide the requested data by accessing the memory at the first physical address (step 408).

According to aspects of the present disclosure, the logic circuit can be re-configured to execute a second function or a different mapping of the logical addresses to physical addresses (step 410). Then the target can receive a second command comprising a request for data from the logical address (step 412) and the logic circuit can generate a second physical address corresponding to the received logical address and the new mapping (step 414). Once the target has the new physical address, it can execute the second command to provide the requested data by accessing the memory at the second physical address (step 416).

Those of skill in the art would appreciate that the various illustrations in the specification and drawings described herein can be implemented as electronic hardware, computer software, or combinations of both. To illustrate this interchangeability of hardware and software, various illustrative blocks, modules, elements, components, methods, and algorithms have been described above generally in terms of their functionality. Whether such functionality is implemented as hardware, software, or a combination depends upon the particular application and design constraints imposed on the overall system. Skilled artisans can implement the described functionality in varying ways for each particular application. Various components and blocks can be arranged differently (for example, arranged in a different order, or partitioned in a different way) all without departing from the scope of the subject technology.

Furthermore, an implementation of the communication protocol can be realized in a centralized fashion in one computer system, or in a distributed fashion where different elements are spread across several interconnected computer systems. Any kind of computer system, or other apparatus adapted for carrying out the methods described herein, is suited to perform the functions described herein.

A typical combination of hardware and software could be a general purpose computer system with a computer program that, when being loaded and executed, controls the computer system such that it carries out the methods described herein. The methods for the communications protocol can also be embedded in a computer program product, which comprises all the features enabling the implementation of the methods described herein, and which, when loaded in a computer system is able to carry out these methods.

Computer program or application in the present context means any expression, in any language, code or notation, of a set of instructions intended to cause a system having an information processing capability to perform a particular function either directly or after either or both of the following a) conversion to another language, code or notation; b) reproduction in a different material form. Significantly, this communications protocol can be embodied in other specific forms without departing from the spirit or essential attributes thereof, and accordingly, reference should be had to the following claims, rather than to the foregoing specification, as indicating the scope of the invention.

The communications protocol has been described in detail with specific reference to these illustrated embodiments. It will be apparent, however, that various modifications and changes can be made within the spirit and scope of the disclosure as described in the foregoing specification, and such modifications and changes are to be considered equivalents and part of this disclosure.

What is claimed is:

1. A method of performing operations in a communications protocol, the method comprising:
providing a target in communication with a host and a memory, wherein the target comprises a logic circuit;
configuring the logic circuit to execute a first function;
receiving, by the target, a first command from the host comprising a request for data from a logical address;
generating, by the logic circuit, a first physical address corresponding to the logical address, in response to the first command;
executing, by the target, the first command to provide the requested data by accessing the memory at the first physical address;
re-configuring the logic circuit to execute a second function;
receiving, by the target, a second command from the host comprising a request for data from the logical address;
generating, by the logic circuit, a second physical address corresponding to the logical address, in response to the second command;
executing, by the target, the second command to provide the requested data by accessing the memory at the second physical address.

2. The method of claim 1, wherein the re-configuring of the logic circuit is in response to a trigger event.

3. The method of claim 1, wherein the trigger event comprises at least one of a memory write failure, reaching a first threshold number of writes to a memory block, reaching a second threshold number of writes to the memory, and reaching a third threshold time in operation.

4. The method of claim 1, wherein the logic circuit is re-configured periodically.

5. The method of claim 1, wherein the logic circuit is implemented in re-configurable logic.

6. The method of claim 5, wherein the re-configurable logic is a field programmable gate array (FPGA).

7. The method of claim 6, wherein the step of re-configuring the logic circuit is performed via partial reconfiguration of the FPGA.

8. The method of claim 1, further including providing a plurality of functions, wherein each function corresponds to a different mapping of logic addresses to physical addresses

9. The method of claim 8, wherein the plurality of functions are stored in the host.

10. The method of claim 1, wherein the first and second physical addresses are stored into a register.

11. A memory controller comprising:
a controller module in communication with a host and a memory, the controller module comprising a logic circuit and configured to:
configure the logic circuit to execute a first function;
receive a first command from the host comprising a request for data from a logical address;
execute the first command to provide the requested data by accessing the memory at a first physical address;
re-configure the logic circuit to execute a second function;
receive a second command comprising a request for data from the logical address; and
execute the second command to provide the requested data by accessing the memory at the second physical address;
wherein the logic circuit is configured to generate the first physical address corresponding to the logical address, in response to the first command, by executing the first function; and
wherein the logic circuit is configured to generate the second physical address corresponding to the logical address, in response to the second command, by executing the second function.

12. The memory controller of claim 11, wherein the controlled module is configured to re-configure the logic circuit in response to a trigger event.

13. The memory controller of claim 11, wherein the trigger event comprises at least one of a memory write failure, reaching a first threshold number of writes to a memory block, reaching a second threshold number of writes to the memory, and reaching a third threshold time in operation.

14. The memory controller of claim 11, wherein the controlled module is configured to re-configure the logic circuit periodically.

15. The memory controller of claim 11, wherein the logic circuit is implemented in re-configurable logic.

16. The memory controller of claim 15, wherein the re-configurable logic is a field programmable gate array (FPGA).

17. The memory controller of claim 16, wherein the controlled module is configured to re-configuring the logic circuit via partial reconfiguration of the FPGA.

18. The memory controller of claim 11, wherein the controlled module is further configured to provide a plurality of functions, wherein each function corresponds to a different mapping of logic addresses to physical addresses

19. The method of claim 18, wherein the plurality of functions are stored in the host.

20. The memory controller of claim 11, wherein the first and second physical addresses are stored into a register.

21. A method of performing operations in a communications protocol, the method comprising:
providing a target in communication with a host and a memory, wherein the memory comprises a logic circuit;
configuring the logic circuit to execute a first function;
receiving, by the target, a first command from the host comprising a request for data from a logical address;
generating, by the logic circuit, a first physical address corresponding to the logical address, in response to the first command;
executing, by the target, the first command to provide the requested data by accessing the memory at the first physical address;
re-configuring the logic circuit to execute a second function;
receiving, by the target, a second command from the host comprising a request for data from the logical address;
generating, by the logic circuit, a second physical address corresponding to the logical address, in response to the second command;
executing, by the target, the second command to provide the requested data by accessing the memory at the second physical address.

22. The method of claim 21 wherein the logic circuit is implemented in at least one of a phase change memory (PCM), a magnetoresistive random-access memory (MRAM), and a resistive random-access memory (ReRAM).

23. A memory controller comprising:
a controller module in communication with a host and a memory comprising a logic circuit, the controller module configured to:
configure the logic circuit to execute a first function;
receive a first command from the host comprising a request for data from a logical address;
execute the first command to provide the requested data by accessing the memory at a first physical address;
re-configure the logic circuit to execute a second function;
receive a second command comprising a request for data from the logical address; and
execute the second command to provide the requested data by accessing the memory at the second physical address;
wherein the logic circuit is configured to generate the first physical address corresponding to the logical address, in response to the first command, by executing the first function; and
wherein the logic circuit is configured to generate the second physical address corresponding to the logical address, in response to the second command, by executing the second function.

24. The memory controller of claim 23 wherein the logic circuit is implemented in at least one of a phase change memory (PCM), a magnetoresistive random-access memory (MRAM), and a resistive random-access memory (ReRAM).
